(19) United States
(12) Patent Application Publication
(10) Pub. No.: US 2012/0120298 A1
(43) Pub. Date: May 17, 2012

(54) LENS MODULE, CAMERA MODULE, AND METHOD FOR MAKING LENS MODULE

(75) Inventors: CHI-WEI CHIU, Tu-Cheng (TW); FANG-SHENG LIN, Tu-Cheng (TW)

(73) Assignee: HON HAI PRECISION INDUSTRY CO., LTD., Tu-Cheng (TW)

(21) Appl. No.: 12/967,054

(22) Filed: Dec. 14, 2010

(30) Foreign Application Priority Data
Nov. 15, 2010 (TW) 99139141

(51) Int. Cl. H04N 5/225; H05K 3/10; G02B 3/14

(52) U.S. Cl. 348/335; 349/200; 29/846; 348/E05.025

(57) ABSTRACT

A lens module includes a lens holder, a liquid crystal lens, wires, and a driving unit. The holder includes an outer surface, a first end portion adjacent to an object side, and a second end portion adjacent to an image side. The first end portion and the second end portion are at opposite sides of the holder. The outer surface connects the first end portion to the second end portion. The holder defines wire grooves in the first end portion and the outer surface. The liquid crystal lens is received in the first end portion. The wires are formed on the first end portion and the outer surface in the grooves. The wires are electrically connected to the liquid crystal lens. The driving unit is electrically connected to the wires and drives the liquid crystal lens to zoom.

### BACKGROUND

1. Technical Field

The present disclosure relates to lens modules, camera modules, and also a method for making the lens modules.

2. Description of Related Art

Optical zooming is a common function of lens modules. Lenses are driven by a driving mechanism to move along an optical axis of the lens module to achieve zooming. The driving mechanism includes a motor, such as a step motor or a voice coil motor and a related guiding mechanism. However, the driving mechanism is bulky, which adds to the size of the lens module.

Therefore, a lens module, a camera module, and a method for making the lens module, which can overcome the limitations described, are needed.

### BRIEF DESCRIPTION OF THE DRAWINGS

FIG. 1 is an isometric and schematic view of a camera module, according to an exemplary embodiment.

FIG. 2 is an exploded view of the camera module of FIG. 1.

### DETAILED DESCRIPTION

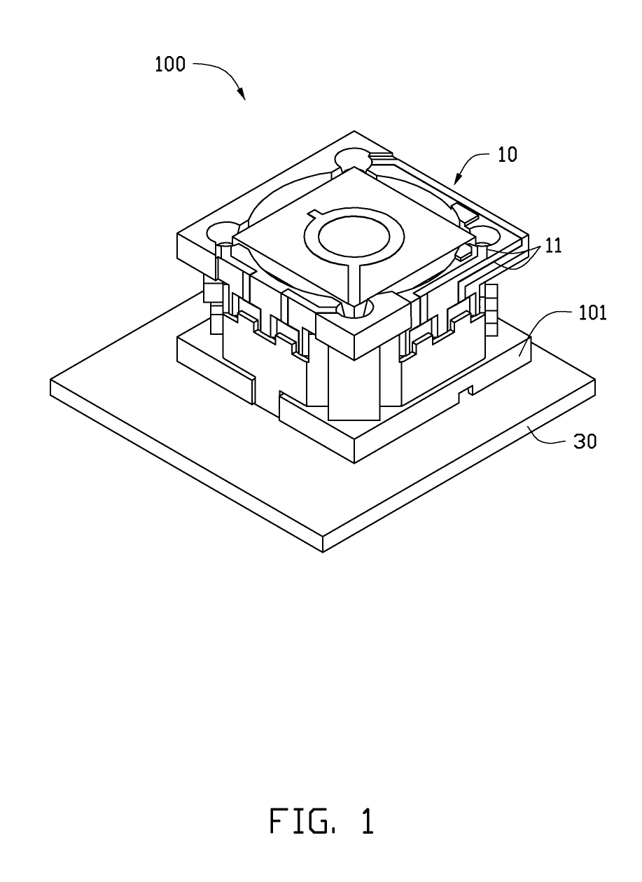

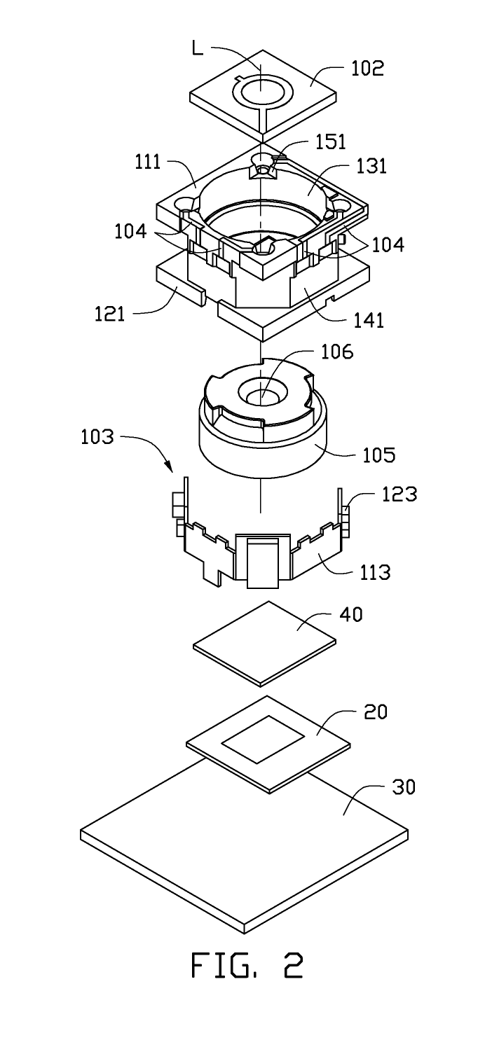

Referring to FIGS. 1 and 2, a camera module 100, according to a first exemplary embodiment, includes a lens module 10, an image sensor 20, a printed circuit board 30, and a cover glass 40.

The lens module 10 includes a lens holder 101, a liquid crystal lens 102, a driving unit 103, a number of wires 104, a lens barrel 105, and an optical lens 106.

Material of the lens holder 101 can be selected from the group consisting of semi-aromatic polyamide based on Ultramid®, thermoplastic polyester based on Pocan®, crosslinked polybutylene terephthalate based on Vestodur®, and liquid crystal polymer based on Vectra®. The lens holder 101 includes an outer surface 141, and a first end portion 111 and a second end portion 121 at opposite sides of the lens holder 101. The first end portion 111 is adjacent to an object side of the lens module 10. The second end portion 121 is adjacent to an image side of the lens module 10. The outer surface 141 connects the first end portion 111 to the second end portion 121. The outer surface 141 encircles and is substantially parallel to an optical axis L of the lens module 101. The lens holder 101 defines a number of wire grooves 11 in the first end portion 111 and the outer surface 141.

The first end portion 111 defines a round receiving space 131. The receiving space 131 is in communication with the wire grooves 11. The liquid crystal lens 102 is received in the receiving space 131. Specifically, the receiving space 131 includes four corner grooves 151. The liquid crystal lens 102 is substantially cuboid. Four corners of the liquid crystal lens 102 are received in the four corner grooves 151 respectively.

The driving unit 103 is mounted on the outer surface 141 of the lens holder 101, which makes the camera module 100 relatively more compact. The driving unit 103 is configured for driving the liquid crystal lens 102 to zoom. The driving unit 103 includes a flexible printed circuit board 113 and a number of driving components 123 electrically mounted on the flexible printed circuit board 113. The driving components 123 include a driver for driving the liquid crystal lens 102. It is to be understood that in alternative embodiments, the driving unit 103 may be mounted on the printed circuit board 30. In such case, the wires 104 extend to the second end portion 121 and are electrically connected to the driving unit 103.

The wires 104 are formed on the outer surface 141 and the first end portion 111 in the wire grooves 11. This also makes the camera module 100 compact.

The lens barrel 105 is received in the lens holder 101. The liquid crystal lens 102 and the lens barrel 105 are arranged in order from the object side to the image side of the lens module 10. The optical lens 106 is received in the lens barrel 105. The optical lens 106 made of glass or plastic is a non-zoom lens. The liquid crystal lens 102 and the optical lens 106 are arranged in order from the object side to the image side of the lens module 10. The optical lens 106 and the liquid crystal lens 102 constitute an imaging lens system for the camera module 100. Changes made to the focal length of the liquid crystal lens 102 results in changes of the effective focal length of the image lens system, thereby achieving optical zoom of the camera module 100.

The image sensor 20 and the cover glass 40 are received in the second end portion 121. The cover glass 40 prevents dust and/or water vapor contaminating the image sensor 20. The liquid crystal lens 102, the optical lens 106, the cover glass 40 and the image sensor 20 are arranged in order from the object side to the image side of the lens module 10.

The lens holder 101 is mounted on the printed circuit board 30 and seals the image sensor 20 in the second end portion 121. The image sensor 20 is positioned on the printed circuit board 30. The printed circuit board 30 is electrically connected to the image sensor 20 and the driving unit 103. For example, the flexible printed circuit board 113 may extend to the printed circuit board 30 and is bonded to the printed circuit board 30 by, for example, soldering.

The camera module 100 integrated with the liquid crystal lens 102, and the driving unit 103 can be directly used in an electronic device, such as a cellar phone. Additional printed circuit board in the electronic device for the driving unit 103 can thus be omitted.

A method for making the lens module 10, according to a second embodiment, includes steps S100 through S110. Step S100: a lens holder 101 of a laser-activated material is formed using an injection-molding process, the lens holder 10 including an outer surface 141, a first end portion 111 and a second end portion 121, the first end portion 111 and the second end portion 121 being at opposite sides of the lens holder 101, the outer surface 141 connecting the first end portion 111 and the second end portion 121. Step S102: Predetermined regions of the outer surface 141 and the first end portion 111 of the lens holder 101 are radiated using a laser beam to define a number of wire grooves 11 therein. Step S104: a number of wires 104 are formed in the wire grooves 11. Step S106: a liquid crystal lens 102 is attached to the first end portion. Step S108: the liquid crystal lens 102 is electrically connected to the wires 104. Step S110: a driving unit 103 is electrically connected to the wires 104, the driving unit 103 configured for driving the liquid crystal lens 102 to zoom.

In the step S100, the laser-activated material can be selected from the group consisted of semi-aromatic polyamide based on Ultramid®, thermoplastic polyester based on Pocan®, crosslinked polybutylene terephthalate based on Vestodur®, liquid crystal polymer based on Vectra®. The lens holder 101 is formed by a single-shot injection-molding process.

In the step S102, the laser beam may be emitted from a diode-pumped infrared laser generator. The wave length of the laser beam can be about 1064 nanometers. The predetermined regions can be designed by computer aided design (CAD) in the computer. The laser beam directly transfers such design from the computer to the lens holder 101. The predetermined regions can be easily changed/adjusted by changing the existing CAD data. Thus, design of the lens module 10 and the camera module 100 can be more flexible.

In step S104, forming the wires 104 in the wires grooves 11 includes sub-steps S140 through S142. Sub-step S140: the lens holder 101 with the wire grooves 11 is cleaned to remove contaminants. Sub-step S142: the lens holder 101 is metalized to form a number of wires 104 in the wire grooves 11.

In the sub-step S142, metallization of the lens holder 101 is achieved with the help of current-free copper baths. This copper baths typically deposit a copper coating with the speed of about 3-5 μm per hour on the lens holder 101. If a greater thickness of copper coating is required, this is achieved using standard electroforming copper baths. Furthermore, application-specific coatings such as Ni, Au, Sn, Sn/Pb, Ag, Ag/Pd, etc., can also be created.

It is to be understood that even though numerous characteristics and advantages of the present embodiments have been set forth in the foregoing description, together with details of the structures and functions of the embodiments, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A lens module, comprising:
a lens holder comprising an outer surface, a first end portion adjacent to an object side and a second end portion adjacent to an image side, the first end portion and the second end portion being at opposite sides of the lens holder, the outer surface connecting the first end portion to the second end portion and being substantially parallel to an optical axis of the lens module, the lens holder defining a plurality of wire grooves in the first end portion and the outer surface;
a liquid crystal lens received in the first end portion;
a plurality of wires formed on the first end portion and the outer surface in the wire grooves, the wires being electrically connected to the liquid crystal lens; and
a driving unit electrically connected to the wires and configured for driving the liquid crystal lens to zoom.

2. The lens module of claim 1, further comprising a lens barrel and an optical lens received in the lens barrel, the lens barrel received in the lens holder, the liquid crystal lens and the lens barrel arranged in order from the object side to the image side of the lens module.

3. The lens module of claim 1, wherein the driving unit is mounted on the outer surface.

4. The lens module of claim 3, wherein the driving unit comprises a flexible printed circuit board and a plurality of driving components electrically mounted on the flexible printed circuit board, the flexible printed circuit board mounted on the outer surface.

5. The lens module of claim 1, wherein the first end portion defines a round receiving space in communication with the wire grooves, the liquid crystal lens being received in the receiving space.

6. The lens module of claim 5, wherein the receiving space comprises four corner grooves, four corners of the liquid crystal lens being received in the four corner grooves respectively.

7. A method for making a lens module, comprising steps of:
forming a lens holder of a laser-activated material using an injection-molding process, the lens holder comprising an outer surface, a first end portion adjacent to an object side and a second end portion adjacent to an image side, the first end portion and the second end portion being at opposite sides of the lens holder, the outer surface connecting the first end portion and the second end portion;
radiating predetermined regions of the outer surface and the first end portion using a laser beam to define a plurality of wire grooves therein;
forming a number of wires in the wire grooves;
attaching a liquid crystal lens to the first end portion;
electrically connecting the liquid crystal lens to the wires; and
electrically connecting a driving unit to the wires, the driving unit configured for driving the liquid crystal lens to zoom.

8. The method of claim 7, further comprising mounting the driving unit on the outer surface.

9. A camera module, comprising:
a lens module of claim 1;
an image sensor received in the second end portion; and
a printed circuit board, the lens holder and the image sensor being mounted on the printed circuit board, the printed circuit board electrically connected to the driving unit and the image sensor.

10. The camera module of claim 9, further comprising a lens barrel and an optical lens received in the lens barrel, the lens barrel received in the lens holder, the liquid crystal lens and the lens barrel arranged in order from the object side to the image side of the lens module.

11. The camera module of claim 9, wherein the driving unit is mounted on the outer surface.

12. The camera module of claim 11, wherein the driving unit comprises a flexible printed circuit board and a plurality of driving components electrically mounted on the flexible printed circuit board, the flexible printed circuit board mounted on the outer surface.

13. The camera module of claim 9, wherein the first end portion defines a round receiving space in communication with the wire grooves, the liquid crystal lens being received in the receiving space.

14. The camera module of claim 13, wherein the receiving space comprises four corner grooves, four corners of the liquid crystal lens being received in the four corner grooves respectively.
